(19) United States
(12) Patent Application Publication
(10) Pub. No.: US 2025/0337352 A1
(43) Pub. Date: Oct. 30, 2025

(54) SYSTEM OF PHOTOVOLTAIC SOLAR PANELS FOR INSTALLATION IN A FIELD FOR AGRICULTURAL OR PASTORAL USE, AND ENERGY PRODUCTION METHOD USING THIS SYTEM

(71) Applicant: Horizonfirm S.r.l., Palermo (IT)

(72) Inventors: Christian CHIARUZZI, Palermo (IT); Agostino COSTANTINO, Palermo (IT)

(21) Appl. No.: 18/879,833

(22) PCT Filed: Jul. 4, 2023
(86) PCT No.: PCT/IB2023/056923

§ 371 Date: Dec. 30, 2024

(30) Foreign Application Priority Data
Jul. 6, 2022 (IT) 102022000014299

(51) Int. Cl. H02S 20/32; H10F 19/90

(52) U.S. Cl. CPC H02S 20/32; H10F 19/904

(57) ABSTRACT

System of photovoltaic solar panels includes solar panels arranged in rows in an open field to facilitate agricultural or pastoral use of areas of the field between the rows. Each solar panel is carried by a support structure, with interposition of a tracking device for rotating the solar panel during an apparent diurnal motion of the sun. Each solar panel includes an array of double-sided photovoltaic solar cells having opposite sides exposed respectively on first and second faces of the solar panel, to collect both direct solar radiation and diffuse solar radiation. The tracking device is configured such that, for the entire duration of the apparent diurnal motion of the sun, the inclination angle formed between the plane of each photovoltaic solar panel and a vertical plane parallel to the longitudinal direction of the row never exceeds the value of 45°, except for a temporary phase at the solar zenith.

### FIELD OF THE INVENTION

The present invention relates to a system of photovoltaic solar panels configured to be installed in an open field for agricultural and/or pastoral use, of the type comprising a plurality of photovoltaic solar panels each including a plurality of photovoltaic solar cells,
in which the photovoltaic solar panels are arranged in parallel and spaced rows, in such a way as to make possible an agricultural or pastoral use of the areas of the field between said rows,
wherein each photovoltaic solar panel has a planar configuration, with a first face intended to face primarily towards the sun and a second face opposite to the first face, and
wherein each photovoltaic solar panel is carried by a support structure, with the interposition of a tracking device including an actuator and an electronic controller configured to rotate the photovoltaic solar panel during the apparent diurnal motion of the sun.

### PRIOR ART

System of photovoltaic solar panels of the type indicated above have been known and used for some time. In a widely used conventional solution, each row of photovoltaic solar panels is associated with one or more tracking devices configured to rotate the panels of the entire row during the apparent diurnal motion of the sun, always maintaining said first face of the photovoltaic solar panels facing towards the sun. In applications where it is desired to make the system of photovoltaic solar panels coexist with a possible agricultural or pastoral management, said solution implies that, in evaluating the space for agricultural or pastoral use, it needs to take into account that the area corresponding to the projection in plan of each row of panels, when they are in a horizontal position, is not available. On the other hand, the space between the rows of panels must be sufficient to allow the passage of machines and equipment for agricultural use, as well as machines and equipment for the maintenance of the photovoltaic system. It follows that for a given area to be cultivated there is a limit to the number of rows of panels that can be installed or, conversely, for a given number of rows of panels to be installed, there is a limit to the area that can be cultivated.

The present invention starts from the desire to find a better compromise between the need to have an electrical energy production as high as possible, through the system of photovoltaic solar panels, and at the same time the need to have a field area as large as possible, available for agricultural or pastoral use.

A system of photovoltaic solar panels, including double-sided solar cells, to be installed on inclined towers integrated with multiple reflecting mirrors, is known from US 2022/069767 A1.

### OBJECT OF THE INVENTION

The object of the present invention is to solve the above problem in a simple and efficient way.

In particular, it is an object of the present invention to provide a system of photovoltaic solar panels which is capable of achieving, for a predetermined extension area of the installation field, the best compromise between the need to obtain a high production of energy and keep a high portion of the available land usable, if desired, for agricultural or pastoral use.

A further object of the present invention is to achieve said objective with extremely simple and efficient means.

A further object of the present invention is to provide a system of the type indicated above which can be easily adapted to each specific application.

A further object of the present invention is to reduce maintenance operations and in particular the need for periodic cleaning of photovoltaic solar panels.

Yet another object of the present invention is to reduce the potential effect of soil rainwash as a result of atmospheric precipitation.

### SUMMARY OF THE INVENTION

In view of achieving one or more of said objectives, the invention relates to a system of photovoltaic solar panels having the features of claim 1.

In one embodiment, each photovoltaic solar panel has solar cells that have a first side relatively more efficient in generating electrical energy and a second side relatively less efficient in generating electrical energy. Each photovoltaic solar panel may have solar cells all having their first side exposed on said first face of the photovoltaic solar panel. In an alternative example, each photovoltaic solar panel has an alternated distribution of first solar cells having their first side exposed on said first face of the photovoltaic solar panel and second solar cells having their first side exposed on said second face of the photovoltaic solar panel.

In case each photovoltaic solar panel has solar cells which all have a relatively more efficient first side exposed on said first face of the photovoltaic solar panel, the system is further characterized in that the tracking device is configured and programmed in a such way that, after the photovoltaic solar panel has been overturned, the face of the photovoltaic solar panel that is exposed to the sun is always the face that was exposed to the sun in the first part of the apparent motion of the sun, so that the overturning of the panel involves passing through a position in which the photovoltaic solar panel is horizontal.

In case each photovoltaic solar panel has a distribution of solar cells having their more efficient first sides exposed alternately on said first face of the photovoltaic solar panel and on said second face of the photovoltaic solar panel, the system is characterized in that the device tracking is configured and programmed in a such way that, after the photovoltaic solar panel is overturned, the face of the photovoltaic solar panel that is exposed to the sun is the face that was not exposed to the sun in the first part of the apparent motion of the sun, so that the overturning of the panel does not necessarily involve passing through a position in which the photovoltaic solar panel is horizontal.

Thanks to the features described above, the system according to the invention allows the need for high energy productivity and the need for high productivity of the area designated for agricultural or pastoral use to be met in an optimal way at the same time.

As can be seen, the solution of the invention arises from the observation that it is possible to renounce the conventional idea of following the apparent motion of the sun by keeping the first face of the photovoltaic solar panel constantly orthogonal to the incidence direction of direct solar radiation, thanks to the possibility to make better use of diffuse solar radiation.

According to the invention, the inclination angle of the photovoltaic solar panel with respect to the vertical never exceeds 45°, and preferably never exceeds 35° and even more preferably never exceeds 20°, i.e. it is always in a position significantly closer to the vertical plane than to the horizontal plane. This trick allows to significantly increase the production of energy due to the photovoltaic cells arranged on the rear face of the panel, which exploit the diffuse light. In this way, for the same amount of solar energy available, it is possible to obtain a production of electrical energy that is only slightly lower than that produced by a conventional system which keeps the front face of the photovoltaic solar panel always orthogonal to the incidence direction of solar radiation. At the same time, the system according to the invention allows for a drastic improvement with respect to the conventional system as regards the area available for agricultural cultivation. This is determined in that a solar panel in a sub-vertical position occupies in plant a significantly smaller space than the space occupied by a conventional photovoltaic solar panel which remains for an extended time, at the middle of the apparent course of the sun, in horizontal position.

Thanks to this feature, the overall result obtainable with the system according to the invention, from the point of view of both the production of electric energy and the exploitation of the field for agricultural uses, is significantly superior to that of a conventional system.

The maintenance of the photovoltaic solar panels in a position close to the vertical position for most of the time of use, also drastically reduces the deterioration of the surface quality of the panels due to atmospheric precipitations and consequently reduces the periodic maintenance operations.

The invention also relates to the method for producing energy using the system described above.

According to a further aspect, the invention also relates to a system of photovoltaic solar panels, comprising a plurality of photovoltaic solar panels each including a plurality of photovoltaic solar cells and intended to be arranged in parallel and spaced rows in an open field, in such a way as to make possible an agricultural or pastoral use of the areas of the field between said rows,
wherein each photovoltaic solar panel has a planar configuration and is carried by a support structure, with or without the interposition of a tracking device configured to rotate the photovoltaic solar panel during the apparent diurnal motion of the sun,
said system being characterized in that for each row of photovoltaic solar panels two photovoltaic solar panels are arranged in a V-shape, forming an angle between them which is never greater than 60° and which has a bisector inclined with respect to a vertical plane parallel to the direction of the row by an angle which is never greater than 60° and preferably never greater than 40°, and
in that the two photovoltaic solar panels arranged in a V-shape have faces facing towards each other and carrying respective arrays of double-sided photovoltaic solar cells with the first face facing towards the inside of the V-shape, in such a way that said solar cells photovoltaic panels exploit both direct solar radiation mainly on the first face, and diffuse solar radiation mainly on the second face, and solar radiation reflected between said faces of the two panels.

In the prior art, the rows of photovoltaic solar panels are spaced up to four folds the orthogonal projection on the ground of the surface of the panels. The V-configuration described here makes it possible to reduce the minimum distance required between the rows (pitch) by about 50%.

A 50% reduction of the orthogonal projection on the ground of the surface of the panels increases the light below the rotation axis.

In a first example, the tracking device is configured to rotate simultaneously and identically the two photovoltaic solar panels arranged in a V-shape during the apparent diurnal motion of the sun.

In an alternative example, the tracking device is configured to rotate the two photovoltaic solar panels arranged in a V-shape during the apparent diurnal motion of the sun, independently of each other.

In a preferred embodiment, a reflecting/diffusing surface, flat or convex, is arranged on the bottom of the space delimited between the two photovoltaic solar panels, which can also be used as a drainage channel capable of conveying rainwater, so that to avoid a risk of soil rainwash or erosion, thus guaranteeing the hydraulic invariance of the installation site.

### DETAILED DESCRIPTION OF THE INVENTION

Further features and advantages of the present invention will appear from the following description with reference to the attached drawings, provided purely by way of non-limiting example, in which:

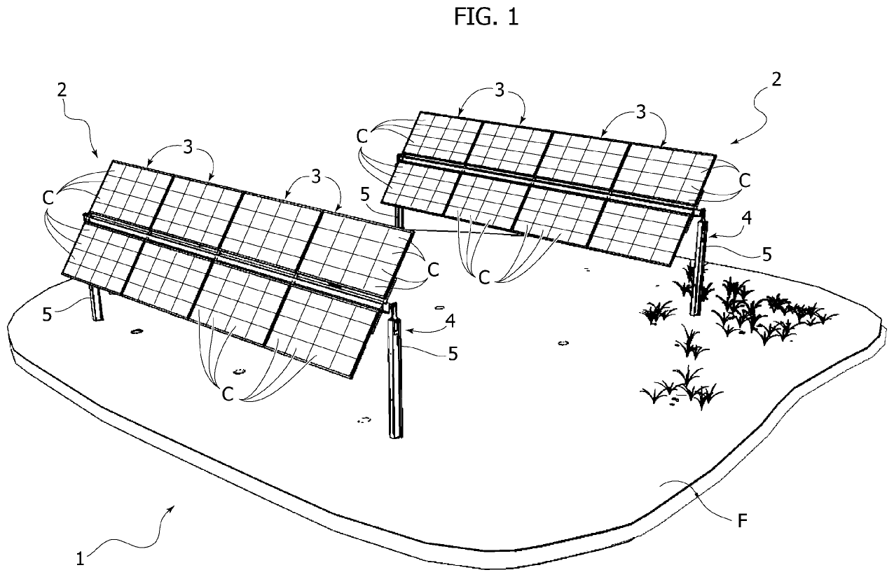

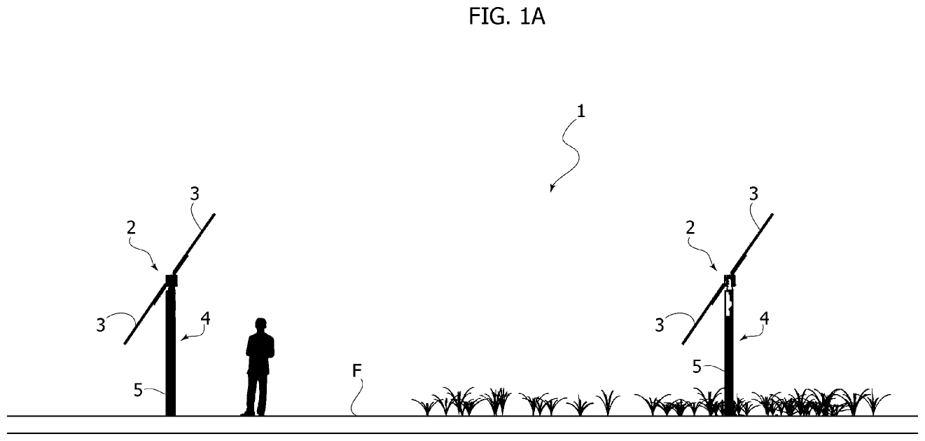

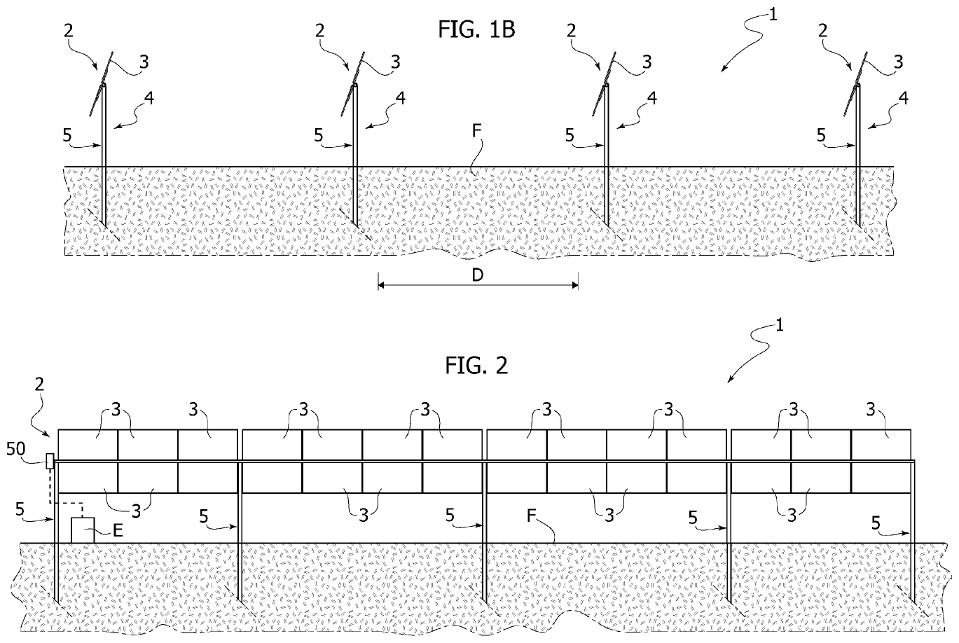

FIGS. 1, 1A and 1B are a perspective view and two side elevation views of a plurality of rows of photovoltaic solar panels constituting a first example of the system according to the invention, installed in a field for agricultural and/or pastoral use,

FIG. 2 is a front view of one of the rows of photovoltaic solar panels illustrated in FIGS. 1, 1A and 1B,

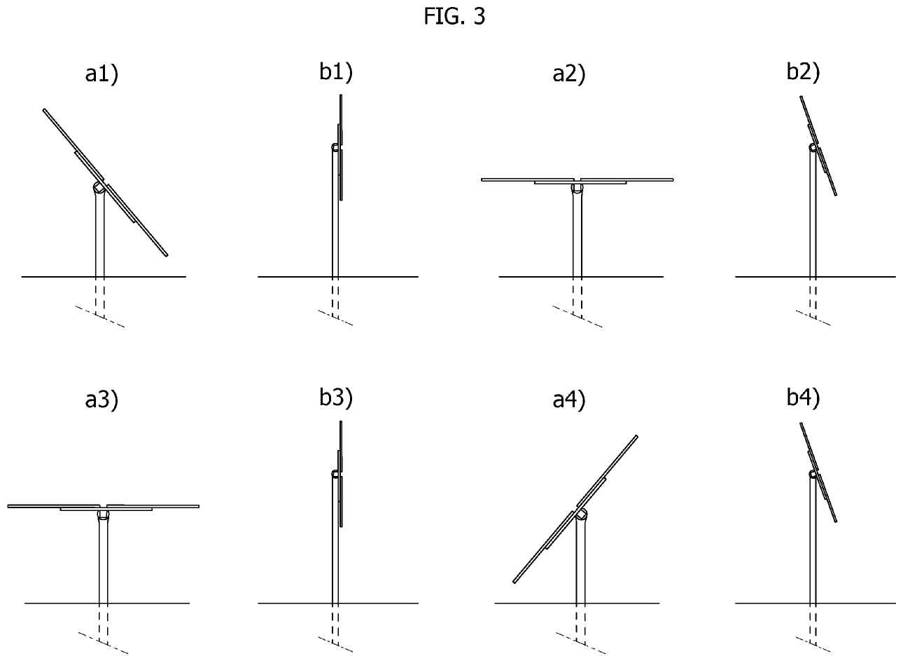

FIGS. 3 a1), a2), a3) and a4) show, by way of example, the positions of a conventional type photovoltaic solar panel respectively at dawn, just before the solar zenith, just after the solar zenith and at sunset,

FIGS. 3 b1), a2), a3) and a4) show the corresponding positions in the case of an embodiment of the system according to the invention,

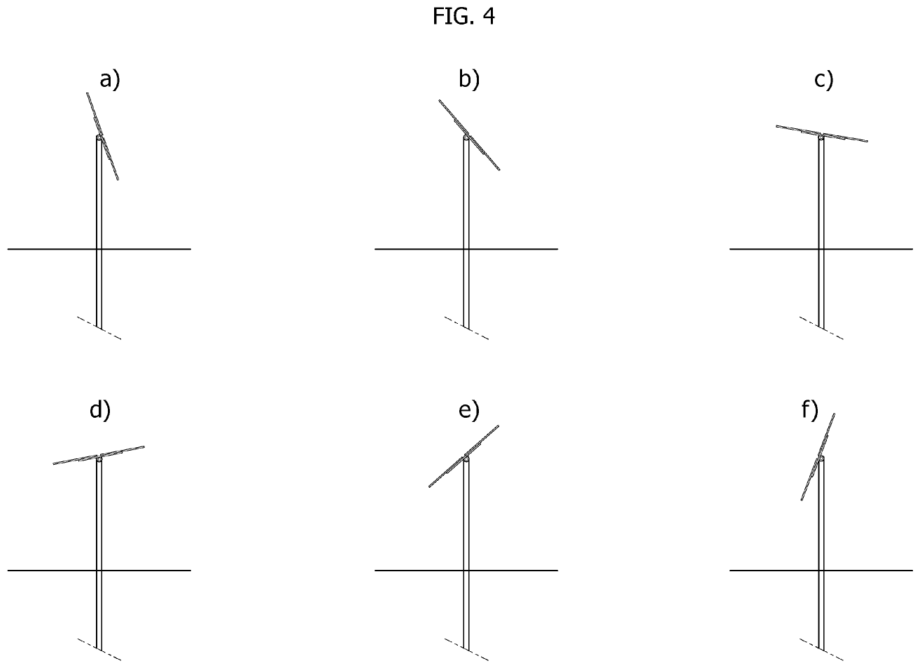

FIG. 4 a), b), c), d), e), f) show different positions progressively taken by a photovoltaic solar panel of a preferred embodiment of the invention, during an overturning phase which is carried out in a time interval for example of about half an hour, substantially at the solar zenith,

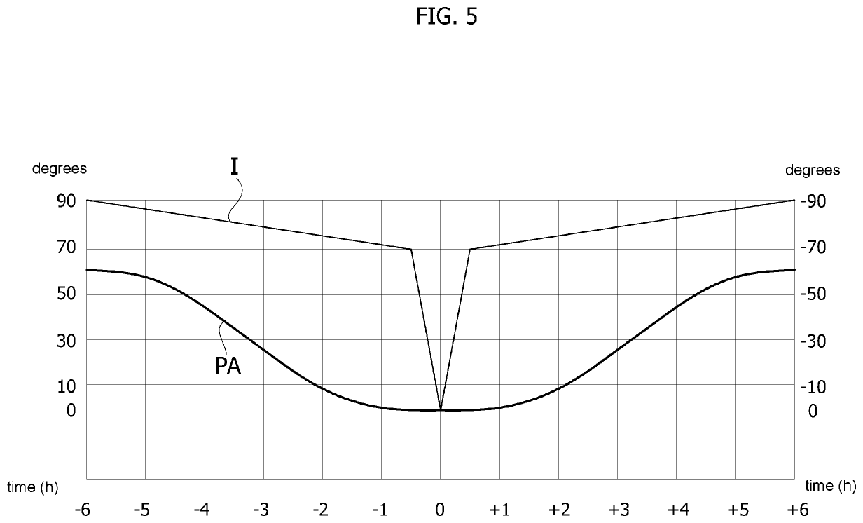

FIG. 5 is a diagram showing the variation of the inclination angle with respect to the horizontal plane of a photovoltaic solar panel forming part of the system according to the invention (line I), and a photovoltaic solar panel according to the conventional technique (line PA),

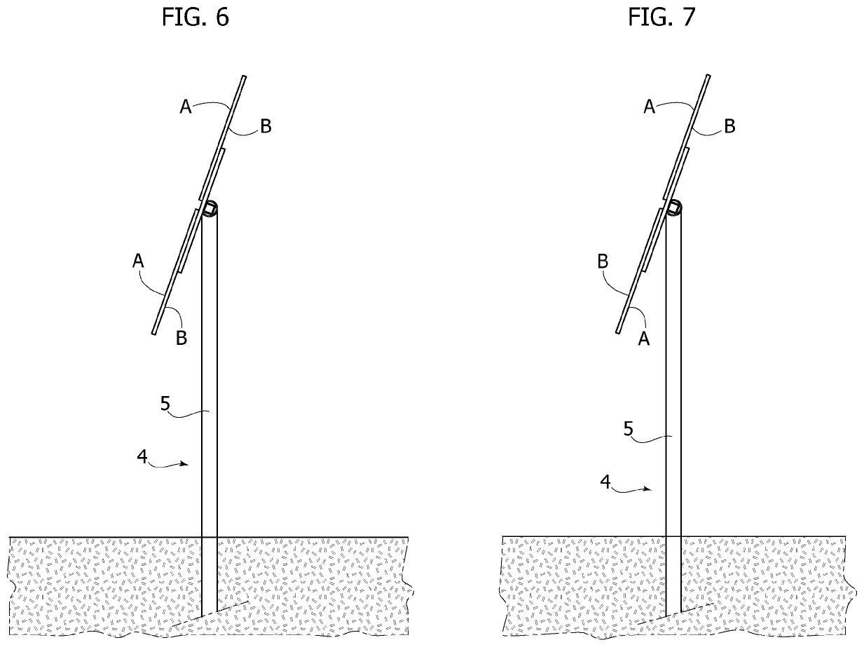

FIGS. 6 and 7 are schematic side views of a photovoltaic solar panel forming part of the system according to the invention, according to two different exemplary embodiments,

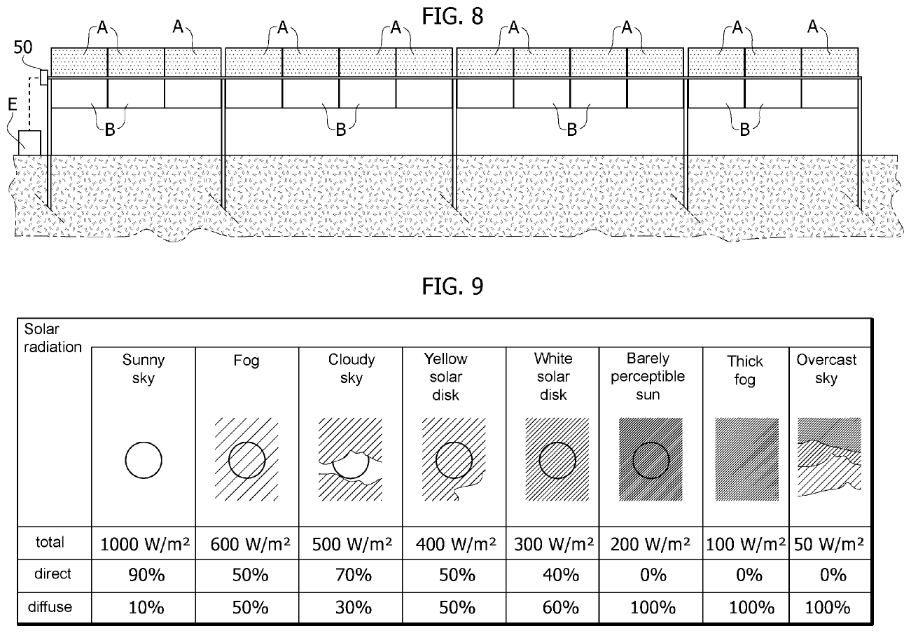

FIG. 8 is a front view of a row of photovoltaic solar panels according to the embodiment of FIG. 6,

FIG. 9 is a table showing, for different atmospheric conditions, the different ratio of the direct component to the diffuse component of the solar radiation collected by a photovoltaic solar panel, and

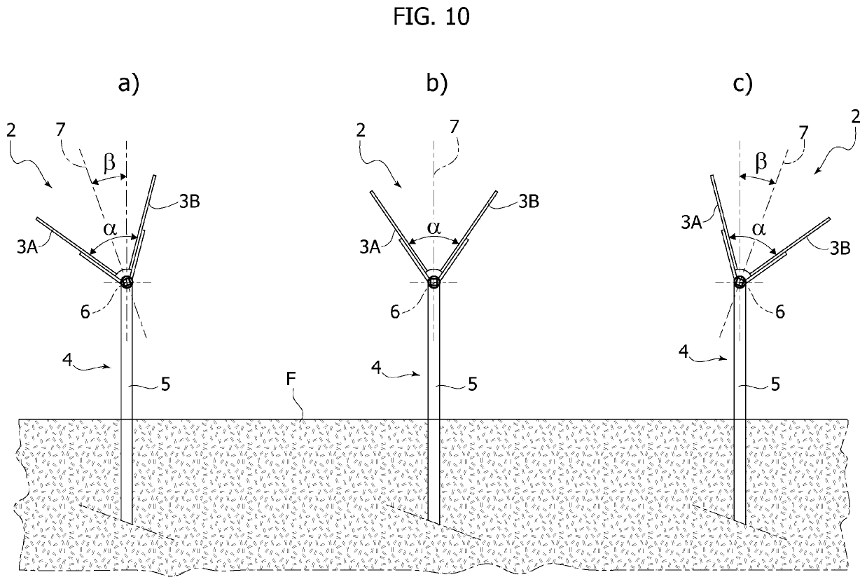

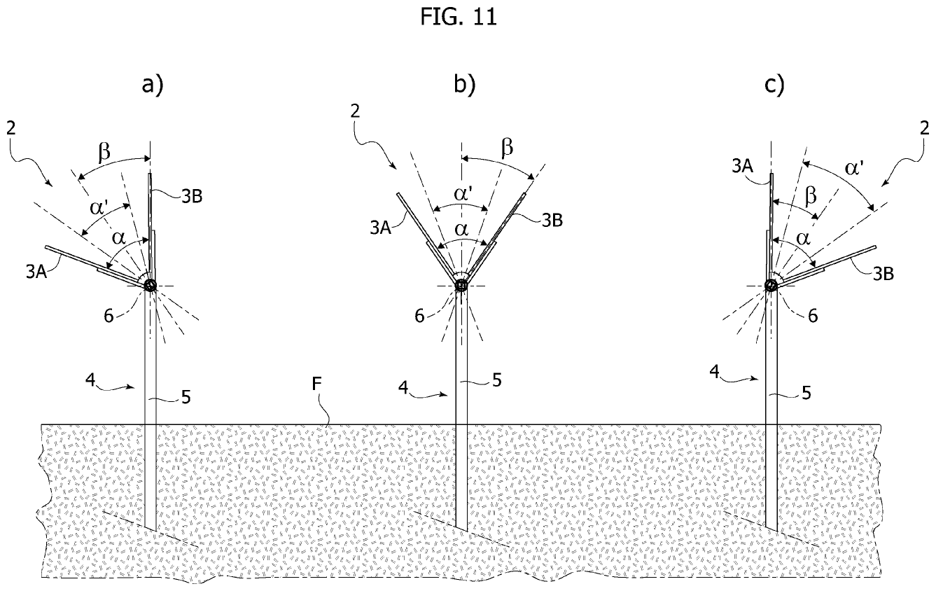

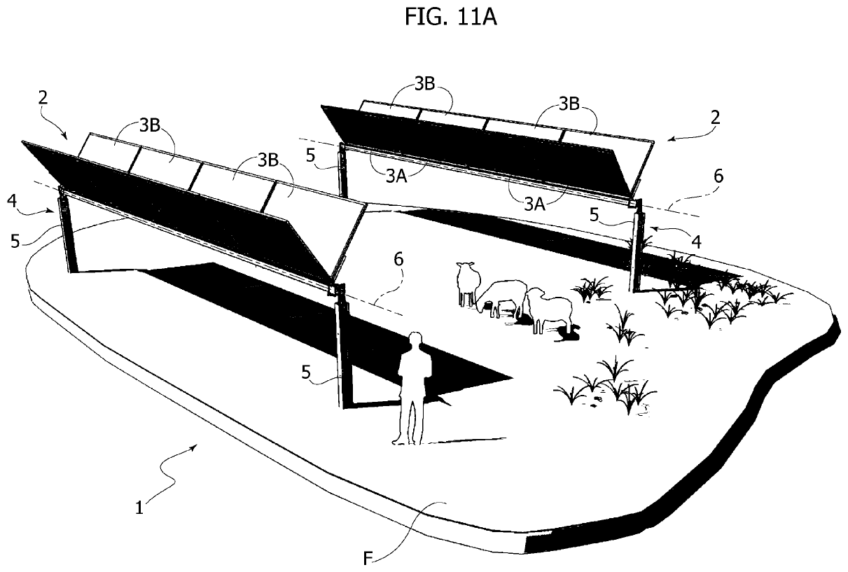

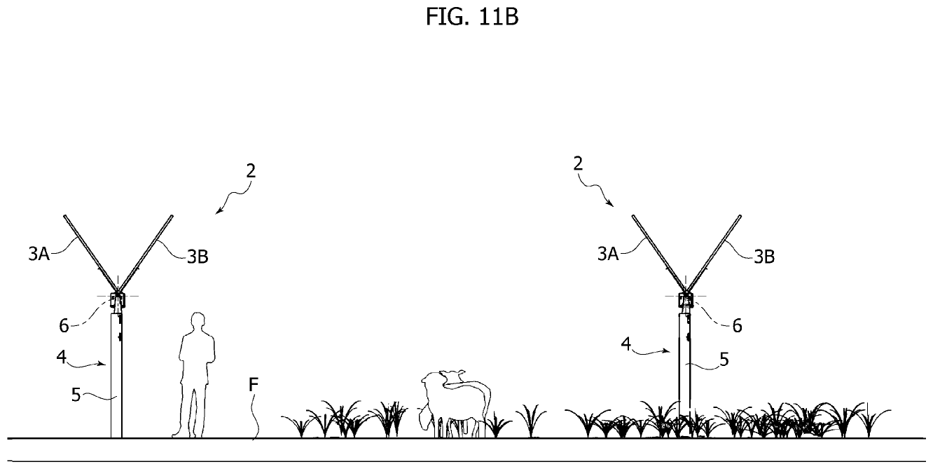

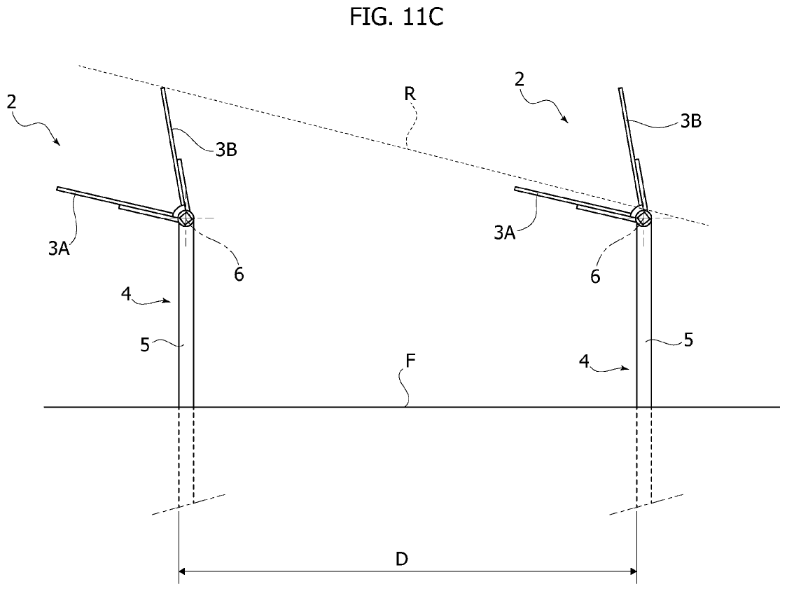

FIGS. 10, 11 are side elevation views illustrating a further example of system of photovoltaic solar panels installed in a field designated for agricultural and/or pastoral use, according to a further aspect of the present invention,

FIG. 11A is a perspective view of the system of FIGS. 10, 11,

FIGS. 11B, 11C are further side views of the system of FIGS. 10, 11, 11A,

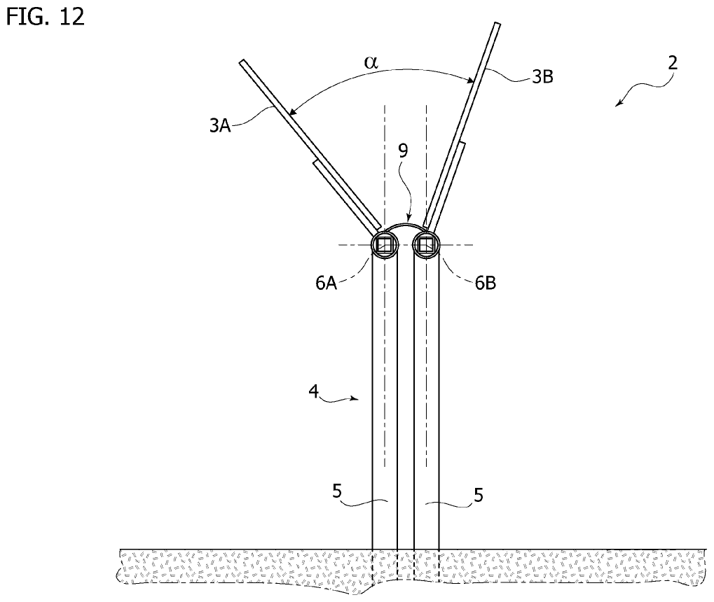

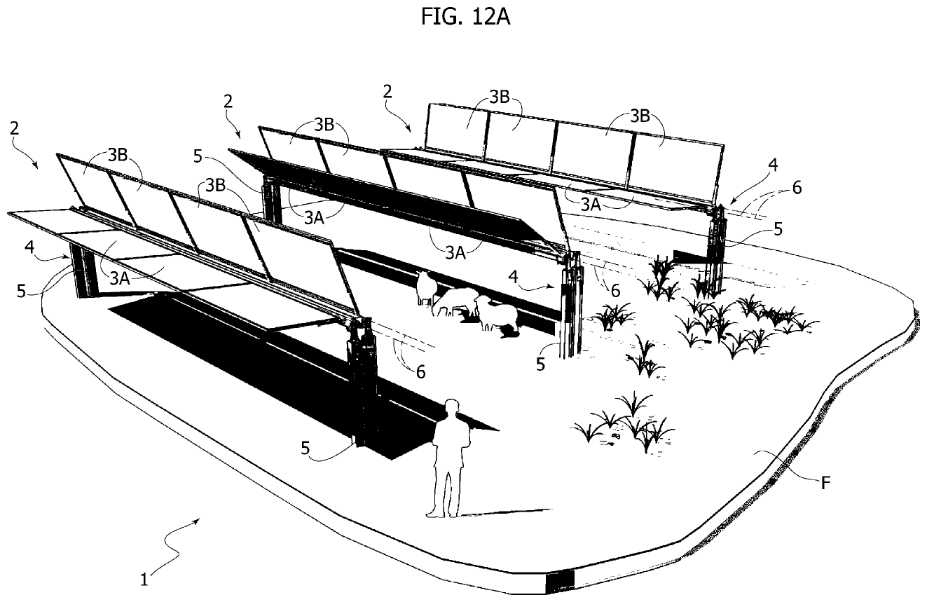

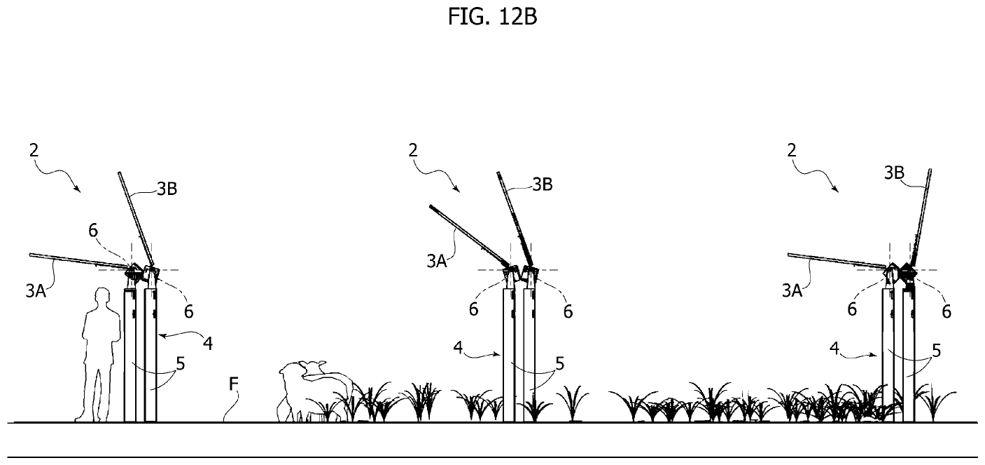

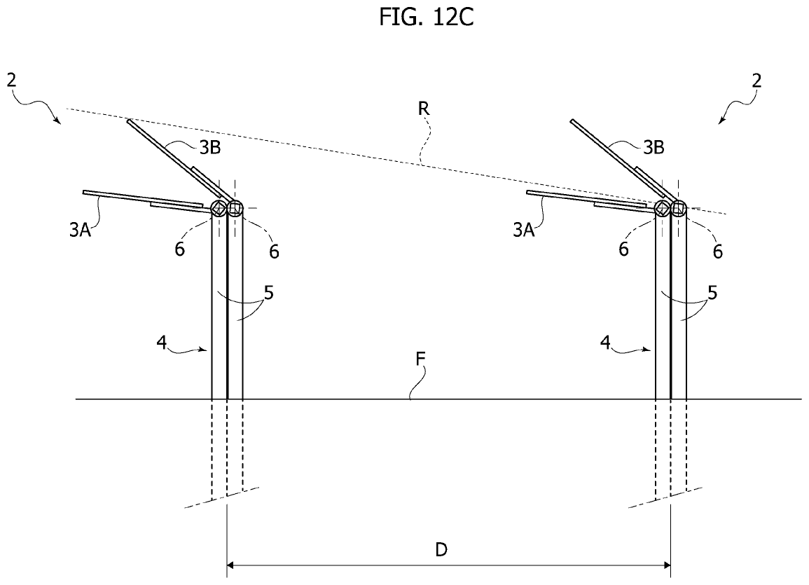

FIG. 12 is a side elevation view of a single row, forming part of a system according to a variant of the solution of FIGS. 10-11C,

FIG. 12A is a perspective view of the system according to the variant of FIG. 12,

FIGS. 12B, 12C are further side views of the system of FIGS. 12, 12A.

FIGS. 1, 1A, 1B, 2, 3, 4, 5 and 6 illustrate a first embodiment of the system according to the invention. The system is indicated as a whole by 1 and comprises a plurality of rows 2 parallel to each other and spaced apart, installed in a field designated for agricultural and/or pastoral use.

Thanks to its features, for the reasons which will become apparent hereinafter, the system according to the invention reconciles at the same time the need for a high productivity of electrical energy and the need for a high productivity of the area of the field designated for agricultural and/or pastoral use.

Each row 2 comprises an arrangement of photovoltaic solar panels 3 arranged substantially in the same plane and each carrying a plurality of double-sided photovoltaic solar cells C having their opposite sides A and B (see FIGS. 6, 7) exposed on the opposite faces of the panel 3.

The A side of each double-sided solar cell is intended to convert direct solar radiation into electrical energy, while the B side is intended to convert diffuse solar radiation.

With reference to FIGS. 6, 7, two alternative solutions can be provided. In the first solution, illustrated in FIG. 6, the cells have all their sides A on the same face of each photovoltaic solar panel 3 (FIG. 6) which is intended to mainly collect direct solar radiation, and all their sides B on the face opposite, which is intended to collect mainly diffuse solar radiation. In a second solution, which is illustrated in FIG. 7 and also in front view in FIG. 8, each photovoltaic solar panel 3 has an alternated distribution of cells with their side A on the first face of the panel and cells with their side B on the first face of the panel.

With reference again to FIGS. 1, 1A, 1B and 2, the accompanying drawings do not illustrate the construction details of the photovoltaic solar panels 3, and in particular they do not illustrate the configuration of the frames carrying said panels, which can be of any known type.

Also not illustrated are the construction details relating to the support structure of each row 2. According to the conventional technique, each row comprises a support structure 4 consisting of a plurality of posts 5 driven into the ground of the installation field, which is indicated by F.

Still according to a per se conventional technique, a tracking device of any known type is interposed between the frame carrying each array of photovoltaic solar panels 3 and the support structure 4, capable of imparting a progressive rotation movement to the photovoltaic solar panels 3 of each row 2 during the apparent diurnal motion of the sun. The construction details of the tracking device are also not illustrated here, both because they can be made in any known way, and because the elimination of these details from the drawings makes the latter more ready and easier to understand. According to the prior art, each tracking device includes an actuator, for example a servo-controlled electric actuator 50 (schematically illustrated in FIGS. 2 and 8) controlled by an electronic controller E (FIGS. 2 and 8) according to a predetermined program. Still according to the prior art, the system is equipped with an electronic controller configured to rotate the photovoltaic solar panels according to any predetermined program, during the apparent diurnal motion of the sun.

FIGS. 3-5 show the main difference between the system according to the invention, in the embodiment described here, and a conventional system which always maintains one face of the photovoltaic solar panels orthogonal to the incidence direction of solar radiation.

In particular, FIG. 5 shows the variation of the angle formed between the plane of the photovoltaic solar panels and the horizontal plane as a function of time, in the case of the embodiment described here (line I) and in the case of a conventional system (PA line). In FIG. 5, on the abscissa axis, time “0” substantially corresponds to the solar zenith and the numbers indicate the hours before and after time “0”. However, it must be considered that the hours of the day to which correspond certain positions of the photovoltaic solar panel vary widely for each specific application, according to the geographical location and according to the day of the year. Therefore, in the diagram of FIG. 5, the numbers on the abscissa axis are only exemplary.

With reference to the example of FIG. 5, in the conventional system (line PA of FIG. 5) at dawn (for example around-6 am) the plane of the photovoltaic solar panel of the conventional system forms an angle of 60° with respect to the horizontal plane, i.e. an angle of 30° with respect to the vertical (see also FIG. 3a1). Still in the case of the conventional system, during the morning, the plane of the photovoltaic solar panel follows the solar path, so the angle formed with respect to the horizontal plane is greatly reduced. For example, in midmorning the angle from the horizontal plane is 30°, which means that the angle from the vertical is 60°. At the end of the morning the photovoltaic solar panel gets closer and closer to the horizontal position, where it remains substantially for a prolonged time, for example from one hour before the solar zenith to one hour after the solar zenith (see also FIGS. 3a2 and 3a3).

Again with reference to FIG. 5, in the case of the conventional system, the rotation of the photovoltaic solar panel continues progressively in the afternoon reproducing in reverse what occurred in the morning, so that the angle formed with respect to the horizontal plane starts to grow again from the value zero up to the value of 60° (see also FIG. 3a4).

As illustrated in FIG. 5, the system according to the invention maintains the photovoltaic solar panel, during the entire apparent diurnal motion of the sun, at an angle with respect to the horizontal plane which, in the example illustrated, varies progressively between 90° and 70°, which corresponds to a variation of the angle formed with respect to the vertical between 0° and 20°, except for a time interval around the solar zenith, for example lasting about half an hour, during which each photovoltaic solar panel is subject to an overturning movement, as will be described in more detail below.

In the example of the invention which is illustrated in FIGS. 3 and 5, in the early morning the photovoltaic solar panel is vertical or nearly vertical. During the morning, the angle formed with respect to the horizontal plane decreases progressively and, in this example, linearly, between the value of 90° and the value of 70°, which means that near the solar zenith the maximum inclination angle with respect to the vertical that is reached by the photovoltaic solar panel (line I of FIG. 5) is about 20°.

With reference to the preferred embodiment which is illustrated here, during a relatively short period of time, in the example of about 30 minutes, each photovoltaic solar panel is overturned, in such a way that at the beginning and at the end of said time interval, the photovoltaic solar panel is inclined on opposite sides of the vertical plane. An example of such an overturning movement is illustrated in FIG. 4, where it can be seen that during said time interval taken to the overturning movement, the photovoltaic solar panel passes from an inclination of 20° with respect to a vertical plane passing through the rotation axis of the panel (FIG. 4a), to an inclination of 20° on the other side of said vertical plane (FIG. 4f). FIGS. 4b, 4c, 4d and 4e show various intermediate positions between the overturning start position and the overturning end position.

In this example, during the entire course of the morning and during the entire course of the afternoon, the photovoltaic solar panel remains in said sub-vertical position, i.e. it never exceeds the inclination angle of 20° with respect to the vertical, but rather get closer to fully vertical position at the beginning and end of the diurnal motion of the sun. The above maximum inclination angle is exceeded only during the above time interval, during which the overturning movement takes place.

The example of FIG. 4 refers to the case of the embodiment of FIG. 6, wherein the cells of the photovoltaic solar panel all have their first sides A exposed on a first face of the panel. Therefore, the overturning movement must be such as to bring the face carrying the sides A of the cells, which during the morning were facing towards the sun, to always be facing towards the sun also during the afternoon, which implies that in the overturning movement the photovoltaic solar panel must pass through the horizontal position (see FIGS. 4c and 4d). However, the embodiment of FIGS. 7, 8 is also provided, in which both the sides A of some cells and the sides B of other cells are exposed on each face of the photovoltaic solar panel 3. In the case of this embodiment, it can therefore be provided that the overturning movement takes place in such a way that in the afternoon the face that does not face towards the sun is the face that faced towards the sun in the morning. In this case, the overturning movement can take place without passing through the horizontal position, but only through a rotation from −20° to +20° with respect to the vertical plane. This feature can be of some importance, as it excludes, even for a very short time interval, that the space between the rows, available for the passage of agricultural machinery and/or machinery for the maintenance of the photovoltaic system, is more limited.

As already discussed above, it is in fact a fundamental element of the present invention to obtain a system which allows the space occupied in plan by the system of photovoltaic solar panels to be considerably reduced, so as to increase the space available for agricultural cultivation.

With reference to FIG. 1B, since the inclination angle of each photovoltaic solar panel 3 with respect to the vertical plane never exceeds that illustrated in FIG. 1B, with the exception of the time interval necessary for the overturning movement of the panels, it follows that between each row and the other there is a space of width D, which is greater than what would be available in a conventional system which had the posts 5 of the rows 2 arranged at the same distance shown in FIG. 1.

Of course, giving up maintaining a main face of the photovoltaic solar panels constantly orthogonal to the incidence direction of solar radiation reduces the amount of energy obtained from direct solar radiation, but the overall result does not involve a substantially decreased energy production, thanks to the fact that the sub-vertical orientation of the photovoltaic solar panels allows greater efficiency in the exploitation of the diffuse solar radiation, through the sides of the photovoltaic cells on the face not exposed to the sun.

FIG. 9 is a table showing that the ratio of the direct solar radiation, which is exploited by the face of the photovoltaic solar panel that faces towards the sun, to the diffuse solar radiation, which is exploited by the face of the photovoltaic solar panel that does not face towards the sun, varies considerably with changes in weather conditions. The table in FIG. 9 also shows the variation of power in Watts per square meter as the atmospheric conditions vary. If in full sunlight the available energy is 1000 W/m2, in progressively worse atmospheric conditions, this energy progressively decreases up to 50 W/m2 when the sky is overcast. At the same time, the proportion between direct solar radiation and diffuse solar radiation ranges from 90%-10% to 0%-100%.

The above further explains how, particularly in geographical areas where the atmospheric conditions can be changeable, the incidence of diffuse solar radiation can be important, which once again demonstrates the advantage of the idea underlying the present invention, consisting in always maintain the photovoltaic solar panels in a sub-vertical position, in which the inclination angle of the photovoltaic solar panels with respect to a vertical plane parallel to the direction of the row does not exceed a predetermined value.

In the example described above, this predetermined maximum value of the inclination angle with respect to the vertical is 20°. However, it falls within the present invention to provide that said angle does not exceed a value of 45°, and preferably that it does not exceed an angle of 35° and even more preferably that it does not exceed an angle of 20°.

In a practical application of the solution in FIG. 1, a simulation campaign was conducted via software, determining, for a given geographical area and for each day of the year, the result obtained in terms of electrical energy produced for different values of the inclination angle of the panels 3, within the variation range of this angle which forms the object of the invention. On the basis of this simulation, it was possible to define an active tracking algorithm whereby at any hour of the day, useful for production, the panels position themselves with the best incidence angle for energy production, within the range of chosen angles.

FIGS. 10, 11, 11A, 11B and 11C illustrate a system of photovoltaic solar panels to be installed in a field designated for agricultural and/or pastoral use, according to a further aspect of the present invention.

In these figures, the parts common to those of FIGS. 1-9 are indicated by the same reference numbers.

In the case of the system of FIGS. 10, 11, 11A, 11B and 11C, for each row 2 of photovoltaic solar panels two series of photovoltaic solar panels 3A, 3B are provided respectively composed of a plurality of double-sided photovoltaic solar cells and arranged in two planes forming a V-shape, which have faces facing towards each other, so that photovoltaic solar cells exploit both direct solar radiation, mainly on the internal face of the V-shape, which is the main face of the cell, and diffuse solar radiation, mainly on the external face, and solar radiation subject to one or more reflections between said faces of the two panels 3A, 3B.

The two panels 3A, 3B can be rotated, by means of a tracking device of any known type (not shown) controlled by an electronic controller around a horizontal axis 6.

In this solution, a single tracking device is configured to cause a simultaneous rotation, around the axis 6, of the two panels 3A, 3B, which therefore always remain in the same relative position.

According to the invention, the panels 3A, 3B form an angle α between them which is never greater than 60°. Furthermore, the bisector 7 of the angle defined between the two photovoltaic solar panels 3A, 3B forms, with respect to the vertical plane, an angle β which never exceeds the value of 60° and preferably never exceeds the value of 45°.

The tracking device is configured to rotate the set of two panels 3A, 3B during the apparent diurnal motion of the sun, so that the bisector 7 is oriented vertically halfway along the apparent motion of the sun (FIG. 10b), while it is inclined on opposite sides (by an angle not exceeding 60° with respect to the vertical) at the beginning and at the end of the apparent diurnal motion of the sun (FIGS. 10a and 10c). During the morning and during the afternoon, the set of two panels is made to rotate progressively from one position to another by the tracking device, according to a predetermined program by which the electronic controller is configured.

FIG. 10 shows an example in which the angle α is equal to approximately 60°, while the angle β at the beginning and at the end of the solar path is equal to approximately 20°.

FIG. 11 is substantially the same as FIG. 10, but shows, by dotted lines, the case in which the two panels form an angle α′ smaller than a between them.

FIGS. 11A and 11B show a perspective view and a further side view of the system of FIGS. 10, 11. These figures show that also in this embodiment the system of the invention is configured for an installation in a field F designated for agricultural and/or pastoral use and aims to make both productions as efficient as possible: the production of electrical energy and the agricultural and/or pastoral production.

FIG. 11C shows that the pitch D between the rows is chosen sufficiently to ensure that at the beginning and at the end of the solar path, when the direction of the incident solar radiation is that indicated by R in the figure, the panels 3B of each row do not shade the panels 3A of the adjacent row.

FIGS. 12, 12A, 12B and 12C refer to a variant of the solution of FIGS. 10, 11, in which the two series of panels 3A, 3B are controlled by respective tracking devices to rotate around respective axes 6A, 6B, which can be coincident with each other or, as in the illustrated case, parallel and slightly spaced apart from each other. Therefore, in this solution the two series of panels 3A, 3B can be rotated both synchronously and with identical rotations, as in the case of the solution of FIGS. 10, 11, and independently of each other, so that the angle α formed between the two series of panels 3A, 3B can be varied over time, as shown in FIG. 12B a), b) and c).

FIG. 12C shows that by exploiting this possibility, the angle α formed between the two series of panels 3A, 3B can be decreased at the beginning and at the end of the solar path, when the direction of the incident solar rays is the one indicated by R, therefore the length of the pitch D at which the panels 3B of each row are prevented from shading the panels 3A of the adjacent row, is proportionally smaller than in the case of FIG. 11C

Preferably, a reflecting/diffusing surface 9 (FIG. 12) is provided on the bottom of the space delimited between the two photovoltaic solar panels arranged in a V-shape, which can be a flat surface or a convex surface (as in the example shown in FIG. 12) and which can also be configured to act as a drainage channel, so as to convey rainwater to dedicated drains and reduce the risk of soil runoff due to atmospheric precipitation.

Of course, without prejudice to the principle of the invention, the details of construction and the embodiments may vary widely with respect to what is described and illustrated purely by way of example, without thereby departing from the scope of the present invention, as defined by the annexed claims.

1. A system of photovoltaic solar panels, configured to be installed in an outdoor field for agricultural and/or pastoral use, comprising:
a plurality of photovoltaic solar panels, each including a plurality of photovoltaic solar cells,
wherein said plurality of photovoltaic solar panels are arranged in parallel and spaced rows, so as to be configured for an agricultural or pastoral use of areas of the outdoor field between said rows,
wherein each photovoltaic solar panel of the plurality of photovoltaic solar panels has a planar configuration, with a first face and a second face opposite to the first face,
wherein each photovoltaic solar panel is carried by a support structure, with an interposition of a tracking device including an actuator and an electronic controller configured to rotate the photovoltaic solar panel during an apparent diurnal motion of the sun,
said system further comprising:
each photovoltaic solar panel includes an array of flat double-sided photovoltaic solar cells, coplanar to each other and arranged in a plane of a respective photovoltaic solar panel,
wherein the double-sided photovoltaic solar cells have opposite sides exposed respectively on said first face and on said second face of the photovoltaic solar panel, so that the first face of the photovoltaic solar panel can mainly collect direct solar radiation, and the second face of the photovoltaic solar panel can mainly collect diffuse solar radiation,
the electronic controller of said tracking device is configured in such a way that, for an entire duration of the apparent diurnal motion of the sun, an inclination angle formed between the plane of each photovoltaic solar panel and a vertical plane parallel to a longitudinal direction of a row of the spaced rows never exceeds a value of 45°, except for a temporary phase at a solar zenith, in which the photovoltaic solar panel is given an overturning movement which is carried out in a time not exceeding one hour,
wherein the electronic controller of said tracking device is configured and programmed in such a way that:
said inclination angle of the photovoltaic solar panel varies progressively between an angle close to 0° at a beginning and at an end of the apparent diurnal motion of the sun, and an angle between 5° and 40° substantially at the solar zenith, and
substantially near the solar zenith, the photovoltaic solar panel is overturned, in a time interval not exceeding one hour, so that at a beginning and at an end of said time interval, the photovoltaic solar panel is inclined on opposite sides with respect to a vertical reference plane parallel to the longitudinal direction of the row.

2. The system according to claim 1, wherein each photovoltaic solar panel has double-sided photovoltaic solar cells which have a first side relatively more efficient in generating electrical energy and a second side relatively less efficient in generating electrical energy.

3. The system according to claim 2, wherein each photovoltaic solar panel has double-sided photovoltaic solar cells all having their first side exposed on said first face of the photovoltaic solar panel.

4. The system according to claim 2, wherein each photovoltaic solar panel has an alternated distribution of first solar cells of the double-sided photovoltaic solar cells having their first side exposed on said first face of the photovoltaic solar panel and second solar cells of the double-sided photovoltaic solar cells having their first side exposed on said second face of the photovoltaic solar panel.

5. The system according to claim 1, wherein each photovoltaic solar panel has double-sided photovoltaic solar cells-which have a first side relatively more efficient in generating electrical energy and a second side relatively less efficient in generating electric energy,
wherein the double-sided photovoltaic solar cells of each photovoltaic solar panel all have their first side exposed on said first face of the photovoltaic solar panel, and
wherein said tracking device is configured and programmed in such a way that after the photovoltaic solar panel has been overturned, a face of the first and second faces of the photovoltaic solar panel that is exposed to the sun is always the face of the first and second faces that was exposed to the sun in the first part of the apparent diurnal motion of the sun, so that the overturning of the photovoltaic solar panel involves passing through a position in which the photovoltaic solar panel is horizontal.

6. The system according to claim 1, wherein each photovoltaic solar panel has double-sided photovoltaic solar cells which have a first side relatively more efficient in generating electrical energy and a second side relatively less efficient in generating electric energy,
wherein each photovoltaic solar panel has an alternated distribution of first solar cells of the double-sided photovoltaic solar cells having their first side exposed on said first face of the photovoltaic solar panel and second solar cells of the double-sided photovoltaic solar cells having their first side exposed on said second face of the photovoltaic solar panel, and
wherein said tracking device is configured and programmed in such a way that after the photovoltaic solar panel has been overturned, a face of the first and second faces of the photovoltaic solar panel that is exposed to the sun is the face of the first and second faces that was not exposed to the sun in the first part of the apparent diurnal motion of the sun, so that the overturning of the panel does not involve passing through a position in which the photovoltaic solar panel is horizontal.

7. A system of photovoltaic solar panels, comprising a plurality of photovoltaic solar panels each including a plurality of photovoltaic solar cells and intended to be arranged in parallel and spaced rows in an open field, so as to make possible an agricultural or pastoral use of the areas of the field between said rows,
wherein each photovoltaic solar panel has a planar configuration and is carried by a support structure, with or without an interposition of a tracking device configured to rotate a photovoltaic solar panel of the plurality of photovoltaic solar panels during an apparent diurnal motion of the sun,
wherein, for each row of photovoltaic solar panels, two series of photovoltaic solar panels are provided, arranged in two planes forming a V-shape, which form first angle between them which is never greater than 60° and which has a bisector inclined with respect to a vertical plane parallel to a direction of the row by a second angle which is never greater than 60°, and
wherein the two series of photovoltaic solar panels arranged in the V-shape have faces facing towards each other and carrying respective arrays of double-sided photovoltaic solar cells, so that said photovoltaic solar cells exploit both direct solar radiation and diffuse solar radiation, and solar radiation reflected between said faces of the two series of photovoltaic solar panels.

8. The system according to claim 7, wherein the system comprises a tracking device configured to rotate simultaneously and identically the two series of photovoltaic solar panels arranged in the V-shape during the apparent diurnal motion of the sun.

9. The system according to claim 7, wherein the system comprises a tracking device configured to rotate the two series of photovoltaic solar panels arranged in the V-shape during the apparent diurnal motion of the sun independently of each other, around two axes coincident with each other or parallel and spaced apart.

10. The system according to claim 7, wherein a flat or convex reflective/diffusing surface is provided on a bottom of a space delimited between the two series of photovoltaic solar panels arranged in the V-shape, which is configured to act as a drainage channel.

11. The system according to claim 7, wherein the rows are arranged with a pitch sufficient to avoid that at a beginning and at an end of the apparent diurnal motion of the sun, the two series of photovoltaic solar panels of each row shade an adjacent row.

12. A method for collecting solar energy, including:
providing a system of photovoltaic solar panels, comprising a plurality of photovoltaic solar panels, each including a plurality of photovoltaic solar cells,
wherein said plurality of photovoltaic solar panels are arranged in parallel and spaced rows in an open field, so as to be configured for an agricultural or pastoral use of areas of the field between said rows,
wherein each photovoltaic solar panel has a planar configuration, with a first face and a second face opposite to the first face,
wherein each photovoltaic solar panel is carried by a support structure, with an interposition of a tracking device including an actuator and an electronic controller configured to rotate the photovoltaic solar panel during an apparent diurnal motion of the sun,
said method further comprising:
each photovoltaic solar panel includes an array of flat double-sided photovoltaic solar cells, coplanar to each other and arranged in a plane of a respective photovoltaic solar panel,
wherein the double-sided photovoltaic solar cells have opposite sides exposed respectively on said first face and on said second face of the photovoltaic solar panel, so that the first face of the photovoltaic solar panel can mainly collect direct solar radiation, and the second face of the photovoltaic solar panel can mainly collect diffuse solar radiation,
said tracking device is controlled in such a way that, for an entire duration of the apparent diurnal motion of the sun, an inclination angle formed between the plane of each photovoltaic solar panel and a vertical plane parallel to a longitudinal direction of a row of the parallel and spaced rows never exceeds a value of 45°, except for a temporary phase at a solar zenith, in which the photovoltaic solar panel is given an overturning movement which is carried out in a time not exceeding one hour,
said tracking device is controlled in such a way that:
said inclination angle of the photovoltaic solar panel varies progressively between an angle close to 0° at a beginning and at an end of the apparent diurnal motion of the sun, and an angle between 5° and 40°, substantially at the solar zenith, and
substantially near the solar zenith, the photovoltaic solar panel is overturned, in a time interval not exceeding one hour, so that at a beginning and at an end of said time interval, the photovoltaic solar panel is inclined on opposite sides with respect to a vertical reference plane parallel to the longitudinal direction of the row.

13. The method according to claim 12, wherein during the apparent diurnal motion of the sun, the inclination angle of the photovoltaic solar panel is varied, within an indicated variation range, according to a law determined on a basis of simulations via software which calculate electrical energy produced for a given geographical area, for each hour of each day of a year and for different values of this inclination angle within the indicated variation range.
